(19) United States
(12) Patent Application Publication
(10) Pub. No.: US 2021/0005424 A1
(43) Pub. Date: Jan. 7, 2021

(54) SHOWER HEAD UNIT AND SYSTEM FOR TREATING SUBSTRATE WITH THE SHOWER HEAD UNIT

(71) Applicant: SEMES CO., LTD., Chungcheongnam-do (KR)

(72) Inventors: Hyoungkyu Son, Daejeon (KR); Hyeon Gyu Kim, Chungcheongnam-do (KR); Seon Ok Kim, Chungcheongnam-do (KR); Yu Dong Han, Seoul (KR)

(21) Appl. No.: 16/914,860

(22) Filed: Jun. 29, 2020

(30) Foreign Application Priority Data
Jul. 3, 2019 (KR) 10-2019-0079874

(51) Int. Cl. H01J 37/32; B05B 1/18; B05B 1/24; H01L 21/67; H01L 21/683

(52) U.S. Cl. CPC H01J 37/3244; B05B 1/185; B05B 1/24; H01L 21/67069; H01J 2237/334; H01L 21/6833; H01J 37/32715; H01J 2237/2007; H01L 21/67103

(57) ABSTRACT

Provided is a shower head unit for control temperature for each area using a planar heating element and a substrate treating system having the same. The substrate treating system includes a housing, a shower head unit installed on an inner upper side of the housing and for entering a process gas for etching a substrate into the housing, and an electrostatic chuck installed on an inner lower side of the housing and for seating the substrate, wherein the shower head unit is installed as a planar heating element in a plurality of areas to control temperature for each area.

### CROSS-REFERENCE TO RELATED APPLICATIONS

This patent application claims the benefit of Korean Patent Application No. 10-2019-0079874, filed on Jul. 3, 2019, which is hereby incorporated by reference in its entirety into this application.

### BACKGROUND

### Field

The present invention relates to a shower head unit and a substrate treating system having the same. More specifically, it relates to a shower head unit with a heater and a substrate treating system having the same.

### Description of the Related Art

The semiconductor device can be manufactured by forming a predetermined pattern on a substrate. When a predetermined pattern is formed on a substrate, a number of processes such as a deposition process, a lithography process, and an etching process can be continuously performed in an equipment used for a semiconductor manufacturing process.

### SUMMARY

The dry etching process used to manufacture semiconductor devices can be performed in a process chamber. In such a process chamber, a shower head is used to supply a process gas for etching a substrate (for example, a wafer).

The shower head is equipped with a heater to heat the process gas. However, since the conventional shower head uses a linear heating element as a heater, temperature control between the center zone and the edge zone may be difficult.

The problem to be solved in the present invention is to provide a shower head unit capable of controlling temperature for each area using a planar heating element.

Further, a problem to be solved in the present invention is to provide a substrate treating system having a shower head unit capable of controlling temperature for each area using a planar heating element.

The problems of the present invention are not limited to the problems mentioned above, and other problems not mentioned will be clearly understood by those skilled in the art from the following description.

One aspect of the substrate treating system of the present invention for achieving the above object comprises a housing; a shower head unit installed on an inner upper side of the housing and for entering a process gas for etching a substrate into the housing; and an electrostatic chuck installed on an inner lower side of the housing and for seating the substrate, wherein the shower head unit is installed as a planar heating element in a plurality of areas to control temperature for each area.

The shower head unit may comprise a shower plate having a plurality of first holes and for spraying the process gas into the housing through the first hole; a lower plate installed on the shower plate and having a plurality of second holes connected to the first hole and formed to be stepped; an upper plate installed on the lower plate and for distributing the process gas to the second hole; and a heating member installed on the shower plate and installed as the planar heating element in a center area, a middle area, and an edge area, respectively.

The heating member may be installed between the lower plate and the upper plate, installed inside the lower plate, or installed between the shower plate and the lower plate.

The heating member may comprise a first heating element installed in the center area as the planar heating element; a second heating element installed in the middle area as the planar heating element; a third heating element installed in the edge area as the planar heating element; a power supplying unit for generating heat by supplying an electrical signal to the first heating element, the second heating element, and the third heating element; a temperature measuring unit for measuring temperature of the first heating element, the second heating element and the third heating element; and a control unit for controlling temperature of the first heating element, the second heating element and the third heating element based on a temperature measurement result.

At least one of the power supplying unit and the temperature measuring unit may be connected to the first heating element, the second heating element and the third heating element through a plurality of third holes formed in the upper plate.

The control unit may uniformly maintain temperature of the first heating element, the second heating element and the third heating element through PID (Proportional Integral Derivative) control.

At least two heating elements of the first heating element, the second heating element and the third heating element may be electrically connected, or the first heating element, the second heating element and the third heating element may be electrically separated.

The third heating element may comprise a plurality of fourth holes, of which inner peripheral surface a ceramic tube is installed on.

The planar heating element is made of a material having a heat resistance property, and the material having a heat resistance property may include at least one component of ceramic, aluminum nitride, and aluminum oxide.

The shower head unit may control temperature for each area by matching a heating area according to a position of a gas discharge hole.

The temperature measuring unit may be a TC (Thermo Couple) sensor.

The second hole may be narrower in width toward a direction, in which the shower plate is located.

The upper plate may include a cooling member therein.

Another aspect of the substrate treating system of the present invention for achieving the above object comprises a housing; a shower head unit installed on an inner upper side of the housing and entering a process gas for etching a substrate into the housing; and an electrostatic chuck installed on an inner lower side of the housing and for seating the substrate, wherein the shower head unit is installed as a planar heating element in a plurality of areas to control temperature for each area, controls temperature for each area by matching a heating area according to a position of a gas discharge hole, and controls temperature for each area based on a temperature measurement result of a planar heating element installed in each area.

One aspect of the shower head unit of the present invention for achieving the above object comprises a shower plate having a plurality of first holes and for spraying the process gas for etching a substrate outside through the first hole; a lower plate installed on the shower plate and having a plurality of second holes connected to the first hole and formed to be stepped; an upper plate installed on the lower plate and for distributing the process gas to the second hole; and a heating member installed on the shower plate and installed as a planar heating element in a plurality of areas to control temperature for each area.

Details of other embodiments are included in the detailed description and drawings.

### BRIEF DESCRIPTION OF THE DRAWINGS

FIG. 1 is a cross-sectional view schematically showing the structure of a substrate treating system having a shower head unit according to an embodiment of the present invention.

FIG. 2 is a cut perspective view showing a schematic structure of a shower head unit according to an embodiment of the present invention.

FIG. 3 is an enlarged cross-sectional view of a cut surface of the shower head unit illustrated in FIG. 2.

FIG. 4 is a first exemplary view showing an installation position of a heating member constituting a shower head unit according to an embodiment of the present invention.

FIG. 5 is a second exemplary view showing an installation position of a heating member constituting a shower head unit according to an embodiment of the present invention.

FIG. 6 is a plan view showing an arrangement structure of a heating member constituting a shower head unit according to an embodiment of the present invention.

FIG. 7 is a cross-sectional view showing an arrangement structure of a heating member constituting a shower head unit according to an embodiment of the present invention.

FIG. 8 is a first exemplary view showing various shapes of a heating member constituting a shower head unit according to an embodiment of the present invention.

FIG. 9 is a second exemplary view showing various shapes of a heating member constituting a shower head unit according to an embodiment of the present invention.

FIG. 10 is a cross-sectional view schematically showing a structure according to another embodiment of a substrate treating system.

FIG. 11 is a cross-sectional view schematically showing a structure according to another embodiment of a substrate treating system.

### DETAILED DESCRIPTION

Hereinafter, preferred embodiments of the present invention will be described in detail with reference to the accompanying drawings. Advantages and features of the present invention, and methods for achieving them will be clarified with reference to embodiments described below in detail together with the accompanying drawings. However, the present invention is not limited to the embodiments disclosed below, but may be implemented in various different forms, and only the embodiments allow the publication of the present invention to be complete, and are provided to fully inform those skilled in the technical field to which the present invention pertains of the scope of the invention, and the invention is only defined by the scope of the claims. The same reference numerals refer to the same components throughout the specification.

When elements or layers are referred to as “on” or “above” of other elements or layers, it includes not only when directly above of the other elements or layers, but also other layer or other element intervened in the middle. On the other hand, when elements are referred to as “directly on” or “directly above,” it indicates that no other element or layer is intervened therebetween.

The spatially relative terms “below,” “beneath,” “lower,” “above,” “upper,” etc., as shown in figures, can be used to easily describe the correlation of an element or components with other elements or components. The spatially relative t€ urns should be understood as terms including the different direction of the element in use or operation in addition to the direction shown in the drawing. For example, if the element shown in the figure is turned over, an element described as “below” or “beneath” the other element may be placed “above” the other element. Accordingly, the exemplary term “below” can include both the directions of below and above. The element can also be oriented in other directions, so that spatially relative terms can be interpreted according to the orientation.

Although the first, second, etc. are used to describe various elements, components and/or sections, these elements, components and/or sections are not limited by these terms. These terms are only used to distinguish one element, component or section from another element, component or section. Therefore, the first element, first component or first section mentioned below may be a second element, second component or second section within the technical spirit of the present invention.

The terminology used herein is for describing the embodiments and is not intended to limit the present invention. In the present specification, the singular form also includes the plural form unless otherwise specified in the phrase. As used herein, “comprises” and/or “comprising” means that the components, steps, operations and/or elements mentioned above do not exclude the presence or additions of one or more other components, steps, operations and/or elements.

Unless otherwise defined, all terms (including technical and scientific terms) used in the present specification may be used as meanings commonly understood by those skilled in the art, to which the present invention pertains. In addition, terms defined in the commonly used dictionary are not ideally or excessively interpreted unless specifically defined.

Hereinafter, exemplary embodiments of the present invention will be described in detail with reference to the accompanying drawings, and in the description with reference to the accompanying drawings, the same or corresponding components are assigned the same reference numbers regardless of reference numerals, and the description overlapped therewith will be omitted.

A sheath heater can be used to heat the process gas supplied to the inside of the process chamber through a shower head. However, in the case of a sheath heater, there is a problem in that it is difficult to control the temperature between the center zone and the edge zone, such as the closer to the heating element, the higher the temperature, and the further away from the heating element, the lower the temperature.

In order to solve this problem, the present invention proposes a shower head unit, using a planar heating element as a heater for heating the process gas, to solve the temperature imbalance between the center zone and the edge zone and a substrate treating system having the same. Hereinafter, the present invention will be described in detail with reference to the drawings and the like.

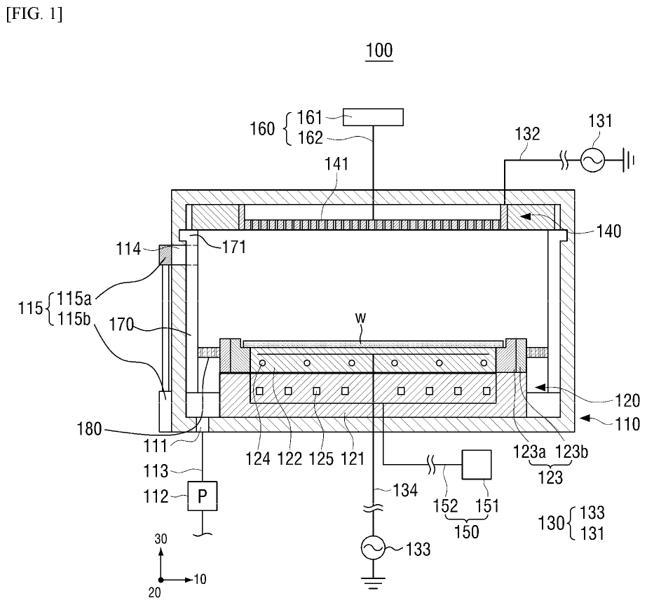

FIG. 1 is a cross-sectional view schematically showing the structure of a substrate treating system having a shower head unit according to an embodiment of the present invention.

According to FIG. 1, the substrate treating system 100 comprises a housing 110, a supporting unit 120, a plasma generating unit 130, a shower head unit 140, a first gas supplying unit 150, a second gas supplying unit 160, a liner (liner or wall-liner) 170 and a baffle unit 180.

The substrate treating system 100 is a system for treating the substrate W using a dry etching process. The substrate treating system 100 may treat the substrate W using, for example, a plasma process.

The housing 110 provides a space, in which the plasma process is performed. The housing 110 may have an exhaust hole 111 in the lower portion.

The exhaust hole 111 may be connected to the exhaust line 113, on which the pump 112 is mounted. The exhaust hole 111 may emit reaction by-products generated in a plasma process and gas remaining inside the housing 110 to the outside of the housing 110 through the exhaust line 113. In this case, the inner space of the housing 110 may be depressurized to a predetermined pressure.

The housing 110 may have an opening 114 on its sidewall. The opening 114 may function as a passage through which the substrate W enters and exits the inside of the housing 110. The opening 114 may be configured to be opened and closed by the door assembly 115.

The door assembly 115 may comprise an outer door 115a and a door driver 115b. The outer door 115a is provided on the outer wall of the housing 110. The outer door 115a may be moved in the vertical direction (i.e., the third direction 30) through the door driver 115b. The door driver 115b may operate using a motor, a hydraulic cylinder, or a pneumatic cylinder.

The supporting unit 120 is installed in the inner lower area of the housing 110. The supporting unit 120 may support the substrate W using electrostatic force. However, the present embodiment is not limited thereto. The supporting unit 120 can also support the substrate W in various ways, such as mechanical clamping, vacuum, and the like.

The supporting unit 120 may include a base 121 and an electrostatic chuck 122 when supporting the substrate W using electrostatic force.

The electrostatic chuck (ESC; 122) is to support the substrate (W) that is seated in its upper area using electrostatic force. The electrostatic chuck 122 may be made of a ceramic material, and may be combined with the base 121 to be fixed on the base 121.

The electrostatic chuck 122 may be installed to be movable in the vertical direction (i.e., the third direction 30) inside the housing 110 using a driving member (not shown). When the electrostatic chuck 122 is formed to be movable in the vertical direction as described above, it may be possible to locate the substrate W in an area exhibiting a more uniform plasma distributio.

The ring assembly 123 is provided to surround the rim of the electrostatic chuck 122. The ring assembly 123 may be provided in a ring shape, and may be configured to support the rim area of the substrate W. The ring assembly 123 may include a focus ring 123a and an insulating ring 123b.

The focus ring 123a is formed inside the insulating ring 123b, and is provided to surround the electrostatic chuck 122. The focus ring 123a may be made of a silicon material, and the plasma may be focused on the substrate W.

The insulating ring 123b is formed outside the focus ring 123a, and is provided to surround the focus ring 123a. The insulating ring 123b may be made of a quartz material.

Meanwhile, the ring assembly 123 may further include an edge ring formed close to the rim of the focus ring 123a. The edge ring may be formed to prevent the side surface of the electrostatic chuck 122 from being damaged by plasma.

The first gas supplying unit 150 is to supply gas to remove foreign substances remaining in the upper portion of the ring assembly 123 or the rim portion of the electrostatic chuck 122. The first gas supplying unit 150 may include a first gas supplying source 151 and a first gas supplying line 152.

The first gas supplying source 151 may supply nitrogen gas N2 gas) as a gas for removing foreign substances. However, the present embodiment is not limited thereto. The first gas supplying source 151 can also supply other gases, cleaners, and the like.

The first gas supplying line 152 is provided between the electrostatic chuck 122 and the ring assembly 123. The first gas supplying line 152 may be formed to be connected, for example, between the electrostatic chuck 122 and the focus ring 123a.

Meanwhile, the first gas supplying line 152 is provided inside the focus ring 123a, and may be formed to be bent to be connected between the electrostatic chuck 122 and the focus ring 123a.

The heating member 124 and the cooling member 125 are provided so that the substrate \V can maintain the process temperature when an etching process is being performed inside the housing 110. To this end, the heating member 124 may be provided as a heating wire, and the cooling member 125 may be provided as a cooling line, through which refrigerant flows.

The heating member 124 and the cooling member 125 may be installed inside the supporting unit 120 so that the substrate W can maintain the process temperature. In one example, the heating member 124 may be installed inside the electrostatic chuck 122, and the cooling member 125 may be installed inside the base 121.

The plasma generating unit 130 generates plasma from gas remaining in the discharge space. Here, the discharge space means a space located above the supporting unit 120 among the inner space of the housing 110.

The plasma generating unit 130 may generate a plasma in the discharge space inside the housing 110 using a capacitively coupled plasma (CCP) source. In this case, the plasma generating unit may use the shower head unit 140 as an upper electrode, and the electrostatic chuck 122 as a lower electrode.

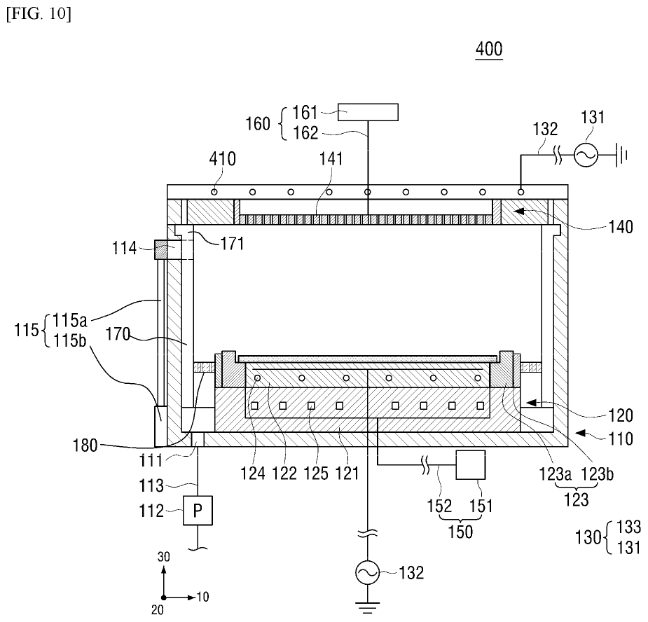

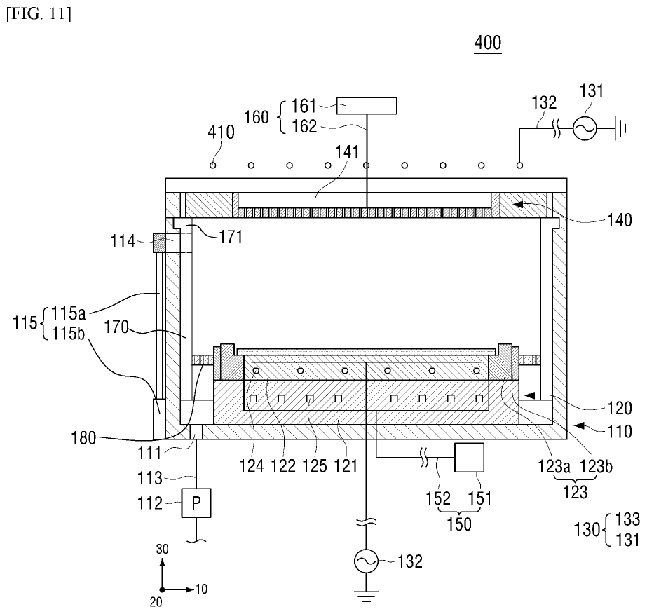

However, the present embodiment is not limited thereto. The plasma generating unit 130 may generate plasma in the discharge space inside the housing 110 using an inductively coupled plasma (ICP) source. In this case, the plasma generating unit 130 may use an antenna 510 installed on the upper portion of the housing 110 as an upper electrode, and an electrostatic chuck 122 as a lower electrode, as shown in FIGS. 10 and 11.

When the plasma generating unit 130 uses an inductively coupled plasma (ICP) source, the structure of the substrate treating system 500 will be described later with reference to FIGS. 10 and 11.

The plasma generating unit 130 may include an upper electrode, a lower electrode, an upper power supply 131 and a lower power supply 133.

As described above, when the plasma generating unit 130 uses a capacitively coupled plasma (CCP) source, the shower head unit 140 may function as an upper electrode, and the electrostatic chuck 122 may function as a lower electrode.

The shower head unit 140 functioning as an upper electrode may be installed to face up and down the electrostatic chuck 122 functioning as a lower electrode inside the housing 110. The shower head unit 140 may include a plurality of gas feeding holes (141) to spray gas into the housing 110, and may be provided to have a larger diameter than the electrostatic chuck 122.

The shower head unit 140 may include a planar heating element therein to solve temperature imbalance between the center area and the edge area. A more detailed description of this will be described later with reference to the drawings and the like.

Meanwhile, the shower head unit 140 may be made of a silicon material or a metal material.

The upper power supply 131 applies power to the upper electrode, that is, the shower head unit 140. The upper power supply 131 may be provided to control characteristics of plasma. The upper power supply 131 may be provided to control, for example, ion bombardment energy.

Although single upper power supply 131 is illustrated in FIG. 1, a plurality of upper power supplies 131 may be provided. When a plurality of upper power supplies 131 are provided, the substrate treating system 100 may further include a first matching network (not shown) electrically connected to the plurality of upper power supplies.

The first matching network may match frequency powers of different sizes input from each upper power supply and apply them to the shower head unit 140.

Meanwhile, a first impedance matching circuit (not shown) may be provided on the first transmission line 132 connecting the upper power supply 131 and the shower head unit 140 for the purpose of impedance matching.

The first impedance matching circuit may act as a lossless passive circuit to effectively (i.e., maximize) transfer electrical energy from the upper power supply 131 to the shower head unit 140.

The lower power supply 133 applies power to the lower electrode, that is, the electrostatic chuck 122. The lower power supply 133 may serve as a plasma source for generating plasma, or may serve to control characteristics of the plasma together with the upper power supply 131.

Although a single lower power supply 133 is illustrated in FIG. 1, it is also possible that a plurality of lower power supplies 131 are provided in the present embodiment like the upper power supply 131. When a plurality of lower power supplies 133 are provided, a second matching network (not shown) electrically connected to the plurality of lower power supplies may be further included.

The second matching network may match the frequency powers of different sizes input from each lower power supply and apply them to the electrostatic chuck 122.

Meanwhile, a second impedance matching circuit (not shown) may be provided on the second transmission line 134 connecting the lower power supply 133 and the electrostatic chuck 122 for the purpose of impedance matching.

The second impedance matching circuit, like the first impedance matching circuit, may act as a lossless passive circuit to effectively (i.e., maximize) transfer electrical energy from the lower power supply 133 to the electrostatic chuck 122.

The second gas supplying unit 160 supplies process gas to the inside of the housing 110 through the shower head unit 140. The second gas supplying unit 160 may include a second gas supplying source 161 and a second gas supplying line 162.

The second gas supplying source 161 is to supply an etching gas used to treat the substrate W as a process gas. The second gas supplying source 161 may supply gas containing a fluorine component (for example, SF6, CF4, etc.) as an etching gas.

A single second gas supplying source 161 may be provided to supply the etching gas to the shower head unit 140. However, the present embodiment is not limited thereto. A plurality of second gas supplying sources 161 may be provided to supply process gas to the shower head unit 140.

The second gas supplying line 162 connects the second gas supplying source 161 and the shower head unit 140. The second gas supplying line 162 transfers the process gas supplied through the second gas supplying source 161 to the shower head unit 140 so that the etching gas can be entered into the housing 110.

Meanwhile, when the shower head unit 140 is divided into a center zone, a middle zone, an edge zone, and the like, the second gas supplying unit 160 may further include a gas distributor (not shown) and a gas distribution line (not shown) to supply a process gas to each area of the shower head unit 140.

The gas distributor distributes a process gas supplied from the second gas supplying source 161 to each area of the shower head unit 140. The gas distributor may be connected to the second gas supplying source 161 through the second gas supplying line 161.

The gas distribution line connects the gas distributor and each area of the shower head unit 140. The gas distribution line can thereby transfer a process gas distributed by the gas distributor to each area of the shower head unit 140.

Meanwhile, the second gas supplying unit 160 may further include a second gas supplying source (not show for supplying a deposition gas.

The second gas supplying source supplies a gas to the shower head unit 140 to protect the side surface of the substrate W pattern so that anisotropic etching is possible. The second gas supplying source may supply a gas such as C₄F₈ and C₂F₄ as a deposition gas.

The liner 170 is for protecting the inner surface of the housing 110 from arc discharge generated during the process gas excitation process, impurities generated during the substrate treating process, and the like. The liner 170 may be provided in a cylindrical shape with upper and lower openings respectively inside the housing 110.

The liner 170 may be provided adjacent to the inner wall of the housing 110. The liner 170 may have a support ring 171 on its upper portion. The support ring 171 is formed to protrude in the outer direction (i.e., the first direction 10) from the upper portion of the liner 170, and may be placed on the top of the housing 110 to support the liner 170.

The baffle unit 180 serves to exhaust process by-products of plasma and unreacted gases. The baffle unit 180 may be installed between the inner wall of the housing 110 and the supporting unit 120.

The baffle unit 180 may be provided in an annular ring shape, and may include a plurality of through holes 181 penetrating in the vertical direction (i.e., the third direction 30). The baffle unit 180 may control the flow of process gas according to the number and shape of the through holes 181.

Next, the shower head unit 140 using a planar heating element that solves the temperature imbalance due to heat conduction will be described,

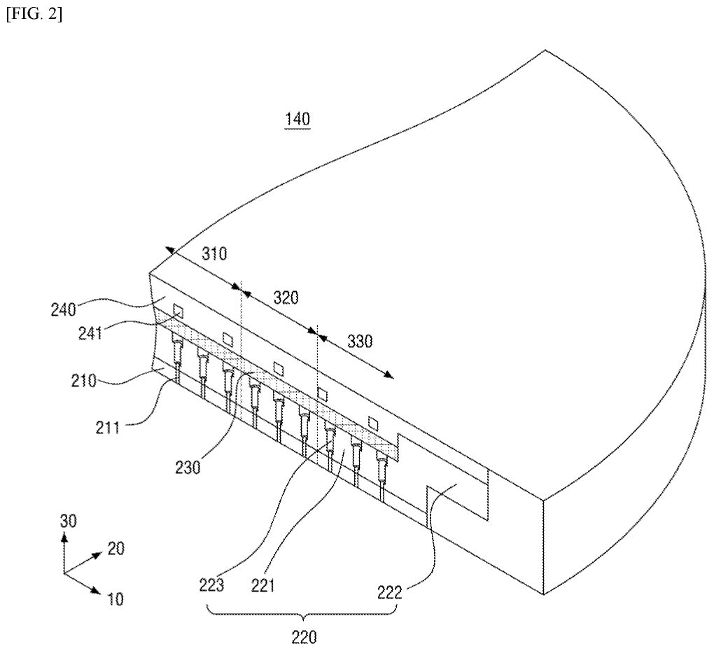

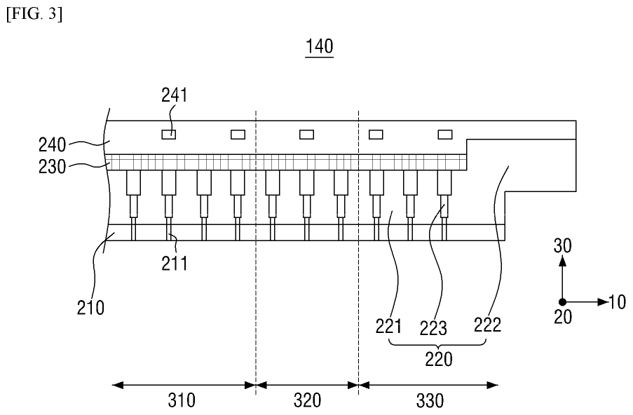

FIG. 2 is a cut perspective view showing a schematic structure of a shower head unit according to an embodiment of the present invention, and FIG. 3 is a cross-sectional view showing an enlarged cut surface of the shower head unit shown in FIG. 2.

According to FIGS. 2 and 3, the shower head unit 140 may include a shower plate 210, a lower plate 220, a heating member 230, and an upper plate 240.

The shower plate 210 directly sprays the process gas used to treat the substrate W into the inner space of the housing 110. To this end, the shower plate 210 may be formed such that its bottom surface is exposed to the inner space of the housing 110.

The shower plate 210 may be formed in a disc shape. The shower plate 210 may include a plurality of gas discharge holes 211 formed in the vertical direction (i.e., in the third direction 30).

The shower plate 210 may be divided into a center area 310, a middle area 320, and an edge area 330. In this case, the plurality of gas discharge holes 211 may be provided in the same number in each of the areas 310, 320, and 330, but different numbers may be provided.

The lower plate 220 is stacked on the upper portion of the shower plate 210. The lower plate 220 may be formed in a disc shape like the shower plate 210.

The lower plate 220 may include a body 221 and a protrusion 222.

The body 221 may comprise a plurality of lower holes 223 formed in the vertical direction (i.e., in the third direction 30). The edge area of the body 221 may be formed to have higher upper and lower ends, respectively, than the middle area.

The lower hole 223 may be provided to be interconnected with the gas discharge hole 211 of the shower plate 210. To this end, the lower hole 223 may be provided in a number corresponding to the gas discharge hole 211 on a one-to-one basis. Meanwhile, the lower hole 223 may be formed in a shape, in which the width narrows toward the downward direction.

The protrusion 222 is formed to extend upward from the body 221. The protrusion 222 is formed in the edge area of the body 221 and can be used for fastening between the lower plate 220 and the upper plate 240.

The heating member 230 is for heating the process gas. The heating member 230 may be installed by being stacked on the upper portion of the lower plate 220.

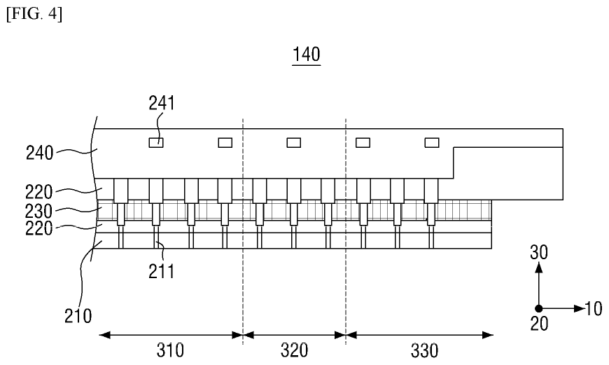

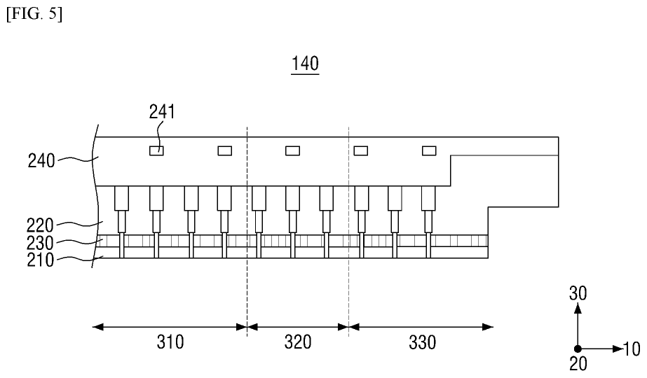

However, the present embodiment is not limited thereto. The heating member 230 may be inserted and installed inside the lower plate 220 as shown in FIG. 4, or inserted and installed between the shower plate 210 and the lower plate 220 as shown in FIG. 5. FIG. 4 is a first exemplary view showing an installation position of a heating member constituting a shower head unit according to an embodiment of the present invention, and FIG. 5 is a second exemplary view showing the installation position of a heating member constituting a shower head unit according to an embodiment of the present invention.

The heating member 230 comprises a thin film heating element that is connected to a power supply in each of the areas 310, 320, and 330, such as the center area 310, the middle area 320, and the edge area 330 such that it may be installed as a planar heating element capable of controlling temperature for each area.

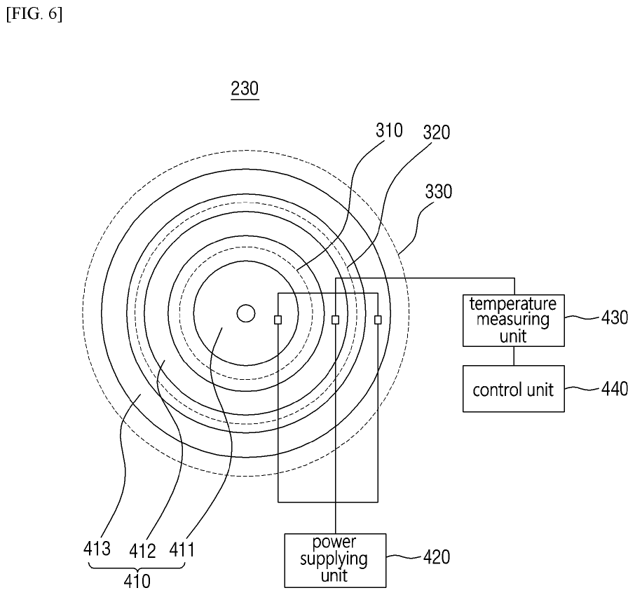

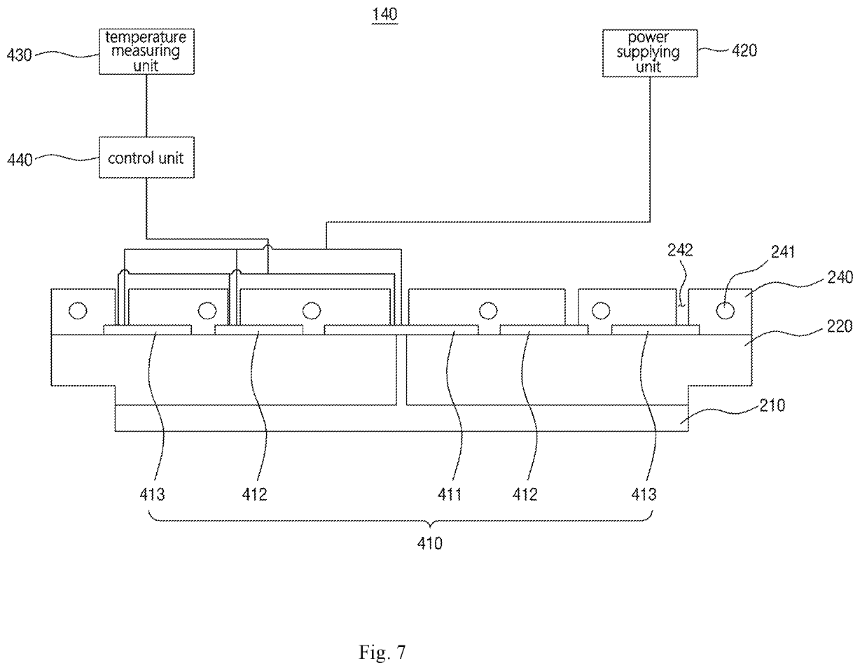

FIG. 6 is a plan view showing an arrangement structure of a heating member constituting a shower head unit according to an embodiment of the present invention, and FIG. 7 is a cross-sectional view showing an arrangement structure of a heating member constituting a shower head unit according to an embodiment of the present invention.

According to FIGS. 6 and 7, the heating member 230 may include a heating element 410, a power supplying unit 420, a temperature measuring unit 430, and a control unit 440.

The heating element 410 is installed in each of the areas 310, 320, and 330, such as the center area 310, the middle area 320, and the edge area 330, to heat the respective areas 310, 320, and 330. In this case, the heating element 410 may include a first heating element 411, a second heating element 412, a third heating element 413, and the like.

The heating element 410 may be formed of a thin film. At least one of t heating elements 410 may be installed in each of the areas 310, 320, and 330 in a ring shape. The heating element 410 may be made of ceramic material.

The heating element 410 may be made of a material having excellent heat resistance property. The heating element 410 may be made of, for example, a material of aluminum nitride (AlN), aluminum oxide (Al₂O₃), or the like.

The power supplying unit 420 is electrically connected to the heating element 410 to supply an electric signal (pulse) to the heating element 410. The heating element 410 may heat each of the areas 310, 320, and 330 using an electric signal supplied from the power supplying unit 420. In this embodiment, it can yield an effect of minimizing the RF impact due to the use of a pulse heater.

Meanwhile, the power supplying unit 420 may be electrically connected to the heating element 410 through a plurality of upper holes 241 formed in the upper plate 240.

The temperature measuring unit 430 measures temperature for each of the areas 310, 320, and 330. The temperature measuring unit 430 may be implemented as a temperature sensor (for example, a TC (Thermo Couple) sensor).

The temperature measuring unit 430 may be electrically connected to the heating element 410 through a plurality of upper holes 241 formed in the upper plate 240 like the power supplying unit 420.

The control unit 440 controls each area 310, 320, 330 to maintain a uniform temperature based on the temperature for each area 310, 320, 330 measured by the temperature measuring unit 430. The control unit 440 may control each area 310, 320, 330 to maintain a uniform temperature using HD (Proportional Integral Derivative) control.

The heating element 410 installed in the respective areas 310, 320, and 330 may be formed in a form that is not interconnected as illustrated in FIGS. 6 and 7. In this case, each heating element 410 may be connected to the power supplying unit 420 through a separate signal line.

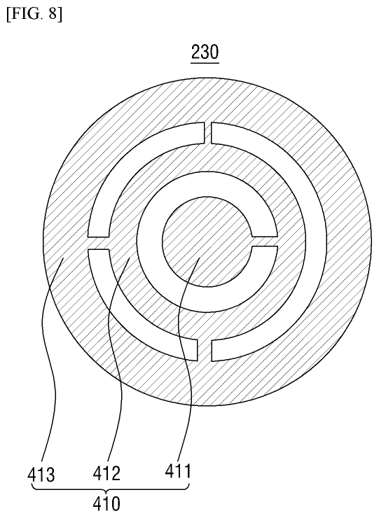

However, the present embodiment is not limited thereto. The heating elements 410 installed in each of the areas 310, 320, and 330 are formed in an interconnected form as illustrated in FIG. 8, and may be implemented as a ring multi pulse heater. In this case, each heating element 410 may be connected to the power supplying unit 420 through a single signal line. FIG. 8 is a first exemplary view showing various shapes of a heating member constituting a shower head unit according to an embodiment of the present invention.

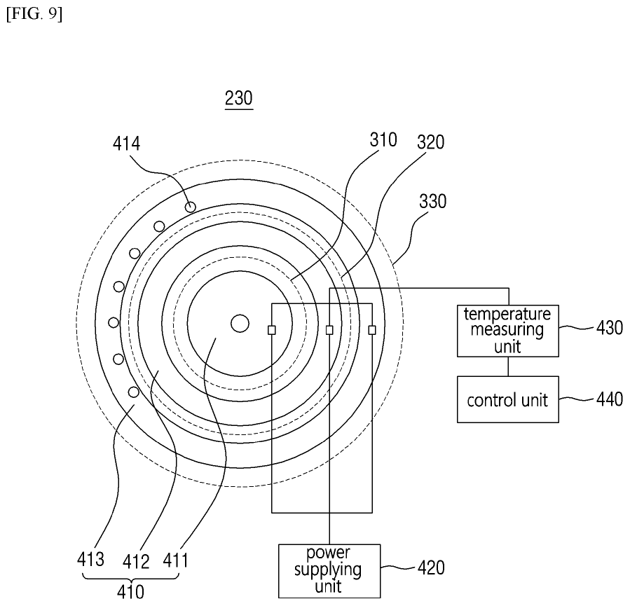

Meanwhile, the third heating element 410c provided in the edge area 330 may include a gas hole 414 as illustrated in FIG. 9. At this time, a ceramic tube may be installed on the inner circumferential surface of the gas hole 414 to prevent a chemical reaction to the gas hole 414. FIG. 9 is a second exemplary view showing various shapes of a heating member constituting a shower head unit according to an embodiment of the present invention.

The heating member 230 constituting the shower head unit 140 has been described above with reference to FIGS. 6 to 9. When the heating member 230 proposed in this embodiment is installed in the shower head unit 140, it functions as a multi heating plate through direct contact heating, and temperature imbalance between the center area 310 and the edge area 330 due to heat conduction may be solved. That is, it can yield an effect that enables uniform temperature control in the center area 310, the middle area 320 and the edge area 330 as compared to the conventional case of providing high temperature heat to the edge area 330 and transferring heat energy from the edge area 330 to the center area 310 by heat conduction.

Further, the heating member 230 can obtain a control knob for the process by matching the heating area according to the position of the gas discharge hole 211, such as the center area 310, the middle area 320 and the edge area 330. Accordingly, the heating member 230 may obtain an effect that enables temperature control for each gas flow zone.

It will be described again with reference to FIGS. 2 and 3.

The upper plate 240 is installed by stacking on the heating member 230. The upper plate 240 may function to distribute and supply process gas entering from the outside to each lower hole 223 of the lower plate 220. Further, the upper plate 240 may be provided with a lower end of the edge area higher than the middle area for fastening with the lower plate 220.

The upper plate 240 may include an upper hole 241 and a cooling member therein.

The upper hole 241 may be connected to the lower hole 223 of the lower plate 220 and the gas discharge hole 211 of the shower plate 210 through the gas hole 414 formed in the heating member 230.

The cooling member may be provided as a passage, through which cooling water or cooling fluid flows inside the upper plate 240, that is, a cooling passage. The cooling member may prevent the shower plate 210 from being heated above a limit temperature.

Next, the structure of the substrate treating system 400 when the plasma generating unit 130 uses an inductively coupled plasma (ICP) source will be described.

FIG. 10 is a cross-sectional view schematically showing a structure according to another embodiment of a substrate treating system. The below description will be referenced to FIG. 10.

According to FIG. 10, the substrate treating system 500 comprises a housing 110, a supporting unit 120, a plasma generating unit 130, a shower head unit 140, a first gas supplying unit 150, a second gas supplying unit 160, a liner 170 and a baffle unit 180.

Since the housing 110, the supporting unit 120, the shower head unit 140, the first gas supplying unit 150, the second gas supplying unit 160, the liner 170, the baffle unit 180, and the like have already been described with reference to FIG. 1, its detailed description is omitted here.

Further, in the case of the shower head unit 140, the above described portions with reference to FIGS. 2 to 9 can be applied to the substrate treating system 500 of FIG. 10 as well.

Therefore, only parts of the substrate treating system 500 of FIG. 10, which are different than the substrate treating system 100 of FIG. 1, will be described.

When the plasma generating unit 130 uses an inductively coupled plasma (ICP) source, the antenna 510 may be used as an upper electrode, and the electrostatic chuck 122 may be used as a lower electrode. At this time, the upper power supply 131 may apply power to the antenna 510.

The antenna 510 functions as an upper electrode and may be installed in the upper portion of the housing 110.

The antenna 510 is equipped with a coil provided to form a closed loop. The antenna 510 generates a magnetic field and an electric field inside the housing 110 based on the power supplied from the upper power supply 131, and functions to excite the gas entered into the housing 110 through the shower head unit 140 to the plasma.

The antenna 510 may be equipped with a coil of a planar spiral. However, the present embodiment is not limited thereto. The structure and size of the coil can be variously changed by those skilled in the art.

Meanwhile, the antenna 510 may be installed separately from the housing 110 on the outside of the housing 110. For example, the antenna 510 may be installed above the upper portion of the housing 110, as shown in FIG. 11. FIG. 11 is a cross-sectional view schematically showing a structure according to another embodiment of a substrate treating system.

Although the embodiments of the present invention have been described with reference to the above and the accompanying drawings, those of ordinary skill in the art to which the present invention pertains could understand that the present invention may be implemented in other specific forms without changing its technical spirit or essential features. Therefore, it should be understood that the embodiments described above are illustrative in all respects and not restrictive.

### REFERENCE NUMERALS

100: substrate treating system
110: housing
120: supporting unit
121: base
122: electrostatic chuck
123: ring assembly
123a: focus ring
123b: insulating ring
124: heating member
125: cooling member
130: plasma generating unit
131: upper power supply
133: lower power supply
140: shower head unit
150: first gas supplying unit
160: second gas supplying unit
170: liner
180: baffle unit
210: shower plate
220: lower plate
230: heating member
240: upper plate
310: center area
320: middle area
330: edge area
410: heating element
420: power supplying unit
430: temperature measuring unit
440: control unit
510: antenna

What is claimed is:

1. A substrate treating system comprising:
a housing;
a shower head unit installed on an inner upper side of the housing and for entering a process gas for etching a substrate into the housing; and
an electrostatic chuck installed on an inner lower side of the housing and for seating the substrate,
wherein the shower head unit is installed as a planar heating element in a plurality of areas to control temperature for each area.

2. The substrate treating system of claim 1,
wherein the shower head unit comprises,
a shower plate having a plurality of first holes and for spraying the process gas into the housing through the first hole;
a lower plate installed on the shower plate and having a plurality of second holes connected to the first hole and formed to be stepped;
an upper plate installed on the lower plate and for distributing the process gas to the second hole; and
a heating member installed on the shower plate and installed as the planar heating element in a center area, a middle area, and an edge area, respectively.

3. The substrate treating system of claim 2,
wherein the heating member is installed between the lower plate and the upper plate, installed inside the lower plate, or installed between the shower plate and the lower plate.

4. The substrate treating system of claim 2,
wherein the heating member comprises,
a first heating element installed in the center area as the planar heating element;
a second heating element installed in the middle area as the planar heating element;
a third heating element installed in the edge area as the planar heating element;
a power supplying unit for generating heat by supplying an electrical signal to the first heating element, the second heating element, and the third heating element;
a temperature measuring unit for measuring temperature of the first heating element, the second heating element and the third heating element; and
a control unit for controlling temperature of the first heating element, the second heating element and the third heating element based on a temperature measurement result.

5. The substrate treating system of claim 4,
wherein at least one of the power supplying unit and the temperature measuring unit is connected to the first heating element, the second heating element and the third heating element through a plurality of third holes formed in the upper plate.

6. The substrate treating system of claim 4,
wherein the control unit uniformly maintains temperature of the first heating element, the second heating element and the third heating element through PID (Proportional Integral Derivative) control.

7. The substrate treating system of claim 4,
wherein at least two heating elements of the first heating element, the second heating element and the third heating element are electrically connected, or the first heating element, the second heating element and the third heating element are electrically separated.

8. The substrate treating system of claim 4,
wherein the third heating element comprises a plurality of fourth holes, of which inner peripheral surface a ceramic tube is installed on.

9. The substrate treating system of claim 1,
wherein the planar heating element is made of a material having a heat resistance property, and the material having a heat resistance property includes at least one component of ceramic, aluminum nitride, and aluminum oxide.

10. The substrate treating system of claim 1,
wherein the shower head unit controls temperature for each area by matching a heating area according to a position of a gas discharge hole.

11. The substrate treating system of claim 4,
wherein the temperature measuring unit is a TC (Thermo Couple) sensor.

12. The substrate treating system of claim 2,
wherein the second hole is narrower in width toward a direction, in which the shower plate is located.

13. The substrate treating system of claim 2,
wherein the upper plate includes a cooling member therein.

14. A substrate treating system comprising:
a housing;
a shower head unit installed on an inner upper side of the housing and for entering a process gas for etching a substrate into the housing; and
an electrostatic chuck installed on an inner lower side of the housing and for seating the substrate,
wherein the shower head unit is installed as a planar heating element in a plurality of areas to control temperature for each area, controls temperature for each area by matching a heating area according to a position of a gas discharge hole, and controls temperature for each area based on a temperature measurement result of a planar heating element installed in each area.

15. A shower head unit comprising:
a shower plate having a plurality of first holes and for spraying a process gas for etching a substrate outside through the first hole;
a lower plate installed on the shower plate and having a plurality of second holes connected to the first hole and formed to be stepped;
an upper plate installed on the lower plate and for distributing the process gas to the second hole; and
a heating member installed on the shower plate and installed as a planar heating element in a plurality of areas to control temperature for each area.

16. The shower head unit of claim 15,
wherein the heating member is installed as the planar heating element in a center area, a middle area, and an edge area, respectively.

17. The shower head unit of claim 16,
wherein the heating member comprises,
a first heating element installed in the center area as the planar heating element;
a second heating element installed in the middle area as the planar heating element;
a third heating element installed in the edge area as the planar heating element;
a power supplying unit for generating heat by supplying an electrical signal to the first heating element, the second heating element, and the third heating element;
a temperature measuring unit for measuring temperatures of the first heating element, the second heating element and the third heating element; and
a control unit for controlling temperature of the first heating element, the second heating element and the third heating element based on a temperature measurement result.

18. The shower head unit of claim 17,
wherein at least two heating elements of the first heating element, the second heating element and the third heating element are electrically connected, or the first heating element, the second heating element and the third heating element are electrically separated.

19. The shower head unit of claim 17,
wherein the third heating element comprises a plurality of fourth holes, of which inner peripheral surface a ceramic tube is installed on.

20. The shower head unit of claim 15,
wherein the hearing element controls temperature for each area by matching a heating area according to a position of a gas discharge hole.
